(19) United States
(12) Patent Application Publication
(10) Pub. No.: US 2026/0109847 A1
(43) Pub. Date: Apr. 23, 2026

(54) RESIN COMPOSITION, CURED LAYER, MANUFACTURING METHOD OF CURED LAYER AND ETCHING METHOD

(71) Applicant: Advanced Echem Materials Company Limited, Taoyuan (TW)

(72) Inventors: Hao-Ding Bai, Taoyuan (TW); Kai-Wen Hu, Taoyuan (TW); Yu-Ning Chen, Taoyuan (TW)

(73) Assignee: Advanced Echem Materials Company Limited, Taoyuan (TW)

(21) Appl. No.: 19/362,459

(22) Filed: Oct. 19, 2025

Related U.S. Application Data
(60) Provisional application No. 63/710,587, filed on Oct. 22, 2024.

(30) Foreign Application Priority Data
Sep. 1, 2025 (TW) 114133286

(51) Int. Cl. C08L 33/06; C08K 5/3492; C09D 7/20; C09D 7/63; C09D 7/65; C09D 133/06; G03F 7/09

(52) U.S. Cl. CPC C08L 33/068; C08K 5/34922; C09D 7/20; C09D 7/63; C09D 7/65; C09D 133/068; G03F 7/091; C08L 2201/56; C08L 2203/20

(57) ABSTRACT

A resin composition, a cured layer, a manufacturing method of a cured layer and an etching method are provided. The resin composition includes a resin (A), a crosslinking agent (B) and a solvent (C). The resin (A) includes a structure represented by the following Formula (A-1). The crosslinking agent (B) includes a polymer including a first structural unit represented by the following Formula (B-1) and a second structural unit represented by the following Formula (B-2). Based on a usage amount of the resin (A) being 100 parts by weight, a usage amount of the crosslinking agent (B) is 60 parts by weight to 150 parts by weight, and a usage amount of the solvent (C) is 2400 parts by weight to 99900 parts by weight.

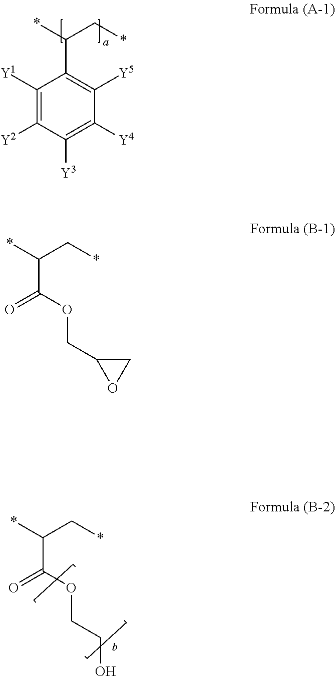

In Formula (A-1), Formula (B-1) and Formula (B-2), the definition of each substituent is the same as defined in the specification.

### CROSS-REFERENCE TO RELATED APPLICATION

This application claims the priority benefit of U.S. provisional patent application Ser. No. 63/710,587, filed on Oct. 22, 2024, and Taiwan application serial no. 114133286, filed on Sep. 1, 2025. The entirety of each of the above-mentioned patent applications is hereby incorporated by reference herein and made a part of this specification.

### BACKGROUND

### Technical Field

The invention relates to a resin composition, and particularly relates to a resin composition, a cured layer, a manufacturing method of a cured layer, and an etching method.

### Related Art

With the development of semiconductor technology, in order to perform high-resolution lithography process, it is necessary to use light with a wavelength of 193 nm as a light source to perform immersion lithography technology. To achieve this requirement, it is necessary to use a bottom antireflective coating (BARC) having high refractive index and low absorption rate. The bottom antireflective coating may be disposed on a substrate, and then a photoresist layer may be formed on the bottom antireflective coating to perform a lithography process on the photoresist layer to form a pattern. By the properties of the high refractive index and low absorption rate of the bottom antireflective coating, light reflection and light absorption between the bottom antireflective coating and the photoresist layer may be reduced, thereby maintaining the intensity of light to ensure optical stability and consistency when the photoresist layer performs the lithography process. Meanwhile, the bottom antireflective coating must also have chemical resistance so that the bottom antireflective coating is not affected by etching solution during the lithography process and loses its properties such as high refractive index and/or low absorption rate. However, currently common bottom antireflective coating has the phenomenon of poor chemical resistance.

### SUMMARY

The invention provides a resin composition, a cured layer, a manufacturing method of a cured layer, and an etching method capable of having good refractive index (n), absorption rate (k), chemical resistance, and etchability resistance.

The invention provides a resin composition including a resin (A), a crosslinking agent (B), and a solvent (C). The resin (A) includes a structure represented by the following Formula (A-1). The crosslinking agent (B) includes a polymer. The polymer includes a first structural unit represented by the following Formula (B-1) and a second structural unit represented by the following Formula (B-2). Based on a usage amount of the resin (A) being 100 parts by weight, a usage amount of the crosslinking agent (B) is 60 parts by weight to 150 parts by weight, and a usage amount of the solvent (C) is 2400 parts by weight to 99900 parts by weight.

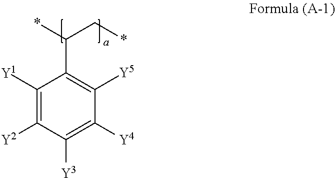

In Formula (A-1), Y¹ to Y⁵ each represent hydrogen or hydroxyl group, and at least two of Y¹ to Y⁵ represent hydroxyl group,
a represents an integer of 5 to 220;
* represents a bonding position.

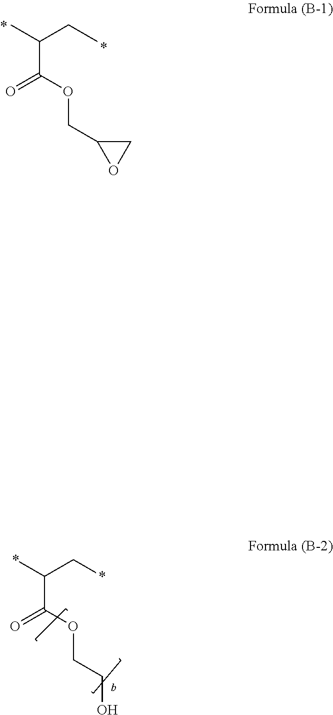

In Formula (B-1) and Formula (B-2), b represents an integer of 1 to 6;
* represents a bonding position.

In an embodiment of the invention, a molar ratio of the first structural unit to the second structural unit is 50:50 to 95:5.

In an embodiment of the invention, a weight average molecular weight of the polymer included in the crosslinking agent (B) is 2000 g/mol to 20000 g/mol.

In an embodiment of the invention, in the Formula (A-1), two of Y¹ to Y⁵ are hydroxyl groups.

In an embodiment of the invention, the resin (A) includes a structural unit represented by the following Formula (A-2):

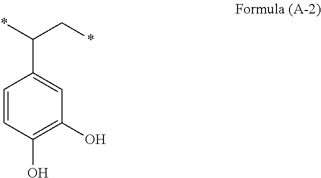

in Formula (A-2), * represents a bonding position;
a weight average molecular weight of the resin (A) is 2000 g/mol to 20000 g/mol.

In an embodiment of the invention, the crosslinking agent (B) further includes a triazine-based compound, a compound having a monomethacrylate functional group, a compound having a dimethacrylate functional group, or a combination thereof.

In an embodiment of the invention, the solvent (C) includes propylene glycol methyl ether (PGME), propylene glycol monomethyl ether acetate (PGMEA), or a combination thereof.

In an embodiment of the invention, the resin composition further includes an additive (D). The additive (D) includes a dispersant, a defoaming agent, a wetting agent, an emulsifier, a leveling agent, an antioxidant, a thermal acid generator, or a combination thereof.

In an embodiment of the invention, the resin composition further includes an additive (D). Based on a usage amount of resin (A) being 100 parts by weight, a usage amount of the additive (D) is greater than 0 part by weight and less than or equal to 25 parts by weight.

A cured layer of the invention is formed by curing the aforementioned resin composition.

A manufacturing method of a cured layer of the invention includes: coating the aforementioned resin composition on a substrate to form a coating film; and baking the coating film to form a cured layer.

In an embodiment of the invention, the baking is performed at a temperature of 150° C. to 250° C.

An etching method of the invention includes: soaking the aforementioned cured layer or the cured layer formed by the aforementioned manufacturing method of a cured layer in an etching solution to perform an etching process.

In an embodiment of the invention, the etching solution includes propylene glycol monomethyl ether acetate, propylene glycol methyl ether, ammonium hydroxide, hydrogen peroxide, water, tetramethylammonium hydroxide, or a combination thereof.

Based on the above, the resin composition of the invention includes a resin (A) having a specific structure and a crosslinking agent (B) including a polymer having a specific structure. Thereby, the resin composition may form a cured layer, a method for manufacturing the cured layer and an etching method having good refractive index, absorption rate, chemical resistance and etchability resistance.

To make the above features and advantages of the invention more apparent and understandable, the following exemplifies embodiments for detailed description.

### DESCRIPTION OF THE EMBODIMENTS

### <Resin Composition>

The invention provides a resin composition including: a resin (A), a crosslinking agent (B), and a solvent (C). In addition, the resin composition of the invention may include other suitable additives according to needs. Hereinafter, each component will be described in detail.

### Resin (A)

The resin (A) includes a structure represented by the following Formula (A-1). In addition, the resin (A) may further include other suitable structures according to needs.

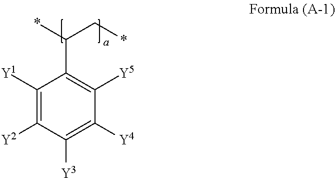

In Formula (A-1), Y¹ to Y⁵ each represent hydrogen or hydroxyl group, and at least two of Y¹ to Y⁵ represent hydroxyl group, a represents an integer of 5 to 220, preferably an integer of 14 to 75;
* represents a bonding position.

In Formula (A-1), at least two of Y¹ to Y⁵ represent hydroxyl group, preferably two of them representing hydroxyl group. For example, when two of Y¹ to Y⁵ represent hydroxyl group, it may be Y¹ and Y² representing hydroxyl group, Y¹ and Y³ representing hydroxyl group, Y¹ and Y⁴ representing hydroxyl group, Y¹ and Y⁵ representing hydroxyl group, Y² and Y³ representing hydroxyl group, Y² and Y⁴ representing hydroxyl group, Y² and Y⁵ representing hydroxyl group, Y³ and Y⁴ representing hydroxyl group, Y³ and Y⁵ representing hydroxyl group, or other combinations. In this embodiment, it is preferable Y³ and Y⁴ representing hydroxyl group.

In this embodiment, the resin (A) may include a structural unit represented by the following Formula (A-2). In addition, the resin (A) may further include other suitable structural units according to needs.

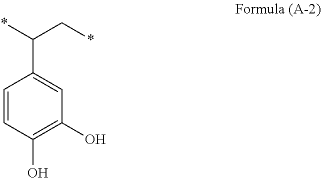

In Formula (A-2), * represents a bonding position. The structural unit represented by Formula (A-2) is a structural unit in the case when Y³ and Y⁴ in Formula (A-1) represent hydroxyl group.

A weight average molecular weight of the resin (A) may be about 2000 g/mol to about 20000 g/mol, preferably about 2000 g/mol to about 10000 g/mol. When the weight average molecular weight of the resin (A) is within the aforementioned range, a cured layer formed from the resin composition including the same may have good chemical resistance and etchability resistance.

When the resin composition includes the resin (A) having a specific structure, the cured layer formed from the resin composition including the same may have better chemical resistance and etchability resistance.

### Crosslinking Agent (B)

The crosslinking agent (B) includes a polymer comprising a first structural unit represented by the following Formula (B-1) and a second structural unit represented by the following Formula (B-2). The polymer may further include other suitable structural units according to needs.

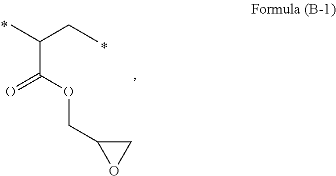

In Formula (B-1), * represents a bonding position.

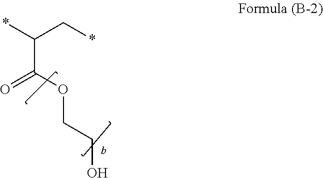

In Formula (B-2), b represents an integer of 1 to 6, preferably an integer of 1 to 5; * represents a bonding position.

In this embodiment, in the polymer, a molar ratio of the first structural unit to the second structural unit is 50:50 to 95:5, preferably 50:50 to 80:20. A weight average molecular weight of the polymer included in the crosslinking agent (B) may be about 2000 g/mol to about 20000 g/mol, preferably about 2000 g/mol to about 10000 g/mol.

In this embodiment, the crosslinking agent (B) may further include a triazine-based compound, a compound having a monomethacrylate functional group, a compound having a dimethacrylate functional group, a combination thereof, or other suitable crosslinking agents. The crosslinking agent (B) may be used alone or in combination of multiple types. The triazine-based compound may include 1,2,3-triazine compound derivative, 1,3,5-triazine compound, or other suitable triazine-based compounds. The compound having a monomethacrylate functional groups may include tetrahydrofurfuryl methacrylate (THFMA), phenyl methacrylate (PBA), tert-butylcyclohexyl methacrylate (TBCHMA), or other suitable compounds. The compound having a dimethacrylate functional group may include 2-(2-ethoxyethoxy)ethyl acrylate (EOEOEA), dipropylene glycol diacrylate (DPGDA), 1,3-butanediol dimethacrylate (BGDMA), polyethylene glycol 200 dimethacrylate (PEG200DMA), or other suitable compounds.

Based on a usage amount of the resin (A) being 100 parts by weight, a usage amount of the crosslinking agent (B) is 60 parts by weight to 150 parts by weight, preferably 60 parts by weight to 100 parts by weight. When the usage amount of crosslinking agent (B) is within the aforementioned range, the cured layer formed by the resin composition including the same may have better chemical resistance and etchability resistance.

When the resin composition includes the crosslinking agent (B) having a specific structure, the cured layer formed by the resin composition including the same may have better chemical resistance and etchability resistance.

### Solvent (C)

The solvent (C) is not particularly limited, and any suitable solvent may be selected according to needs. In this embodiment, the solvent (C) may include propylene glycol methyl ether, propylene glycol monomethyl ether acetate, a combination thereof, or other suitable solvents. The solvent (C) may be used alone or in combination of multiple types.

Based on the usage amount of the resin (A) being 100 parts by weight, a usage amount of the solvent (C) is 2400 parts by weight to 99900 parts by weight, preferably 20000 parts by weight to 60000 parts by weight.

### Additive (D)

The resin composition may further include an additive (D). The additive (D) is not particularly limited, and any suitable additive may be selected according to needs. For example, the additive (D) may include a dispersant, a defoaming agent, a wetting agent, an emulsifier, a leveling agent, an antioxidant, a thermal acid generator, a combination thereof, or other suitable additives. In this embodiment, the resin composition may be free of the thermal acid generator while having good chemical resistance.

Based on the usage amount of resin (A) being 100 parts by weight, a usage amount of the additive (D) is greater than 0 part by weight and less than or equal to 25 parts by weight, preferably 2 parts by weight to 18 parts by weight.

### <Manufacturing Method of Resin Composition>

A manufacturing method of a resin composition is not particularly limited. For example, the resin (A), the crosslinking agent (B), and the solvent (C) are placed in a stirrer and stirred to uniformly mix them into a solution state. If necessary, other suitable additives may also be added thereto and mixed uniformly to obtain a liquid resin composition.

### <Manufacturing Method of Cured Layer>

An exemplary embodiment of the invention provides a manufacturing method of a cured layer comprising coating the aforementioned resin composition on a substrate to form a coating film; and baking the coating film to form a cured layer.

For example, after coating the resin composition on a substrate to form a coating film, baking is performed at a temperature of 150° C. to 250° C. (preferably about 215° C.) for 0.5 minutes to 3 minutes (preferably about 1 minute) to form a cured layer having a thickness of 5 nm to 15 nm on the substrate.

The substrate is not particularly limited, but its material is preferably silicon, silicon oxide, aluminum, aluminum oxide, copper, metal oxide, or metal nitride. The type of the substrate is not particularly limited, but may be a glass substrate, plastic substrate material (for example, polyethersulfone (PES) plate, polycarbonate (PC) plate, or polyimide (PI) film), or other suitable substrate types.

The coating method is not particularly limited, but spray coating, roll coating, spin coating, screen printing, spin coating, or similar methods may be used. Generally, spin coating is widely used. In addition, a coating film is formed, and subsequently in some cases, residual solvent may be partially removed under reduced pressure.

<Cured layer>

An exemplary embodiment of the invention provides a cured layer formed by curing the aforementioned resin composition. In this embodiment, the cured layer may be an etch-resistant layer. The cured layer may be formed by the aforementioned manufacturing method of a cured layer.

### <Etching Method>

An exemplary embodiment of the invention provides an etching method including soaking the aforementioned cured layer or the cured layer formed by the aforementioned manufacturing method of a cured layer in an etching solution to perform an etching process.

The etching solution is not particularly limited, and any suitable etching solution may be selected according to needs. In this embodiment, the etching solution may be a solvent formed by mixing PGMEA and PGME (weight ratio 3:7) or an alkaline etching solution. The alkaline etching solution may include ammonium hydroxide (NH₄OH), hydrogen peroxide (H₂O₂), water (H₂O), tetramethyl ammonium hydroxide (TMAH), or a combination thereof, preferably a combination of NH₄OH, H₂O₂, and H₂O. When the alkaline etching solution is composed of NH₄OH, H₂O₂, and H₂O, a mixing ratio (weight ratio) of NH₄OH, H₂O₂, and H₂O may be 0.25:1:5 to 1:10:120, preferably 0.25:1:5 to 1:1:5.

The temperature for performing the etching process and other steps included in the etching method may be content well known to those skilled in the art, and will not be further described herein.

Hereinafter, the invention will be described in detail with reference to examples. The following examples are provided for describing the present invention, and the scope of the invention includes the scope described in the following claims and substitutes and modifications thereof, and is not limited to the scope of the examples.

### Examples of Resin Composition and Cured Layer

The Example 1 to Example 13 and Comparative Example 1 to Comparative Example 15 of the resin composition and cured layer are described hereinafter:

### Example 1

a. Resin Composition

100 parts by weight of resin A-1, 66.67 parts by weight of crosslinking agent B-1, and 2.033 parts by weight of additive D-1 were added to 40482 parts by weight of propylene glycol monomethyl ether acetate. And after stirring uniformly with a stirrer, the resin composition of Example 1 was obtained.

b. Cured Layer

The resin composition obtained in the Example was coated on a substrate (for example, silicon substrate) by spin coating method (spin coater model: TEL Clean Track MK-8, manufactured by Tokyo Electron Limited, rotation speed being about 1500 rpm). Then, baking was performed at a temperature of 215° C. for 1 minute to form a cured layer with a thickness of 100±50 Å. The obtained cured layer was evaluated by the following evaluation methods, and the results are shown in Table 2.

### Example 2 to Example 13 and Comparative Example 1 to Comparative Example 15

The resin compositions of Example 2 to Example 13 and Comparative Example 1 to Comparative Example 15 were prepared by the same steps as Example 1. The difference was that the types of components and the usage amount thereof in the resin composition were changed (as shown in Table 2), wherein the components/compounds corresponding to the labels in Table 2 are as shown in Table 1. The obtained resin compositions were formed into cured layers and evaluated by the following evaluation methods, and the results are shown in Table 2. rp-28,TaE,M

TABLE 1

| | Label | Component/Compound |
|---|---|---|
| Resin (A) | A-1 | Structure represented by Formula (A-1), wherein Y¹, Y², and Y⁵ |
| | | represent hydrogen, Y³ and Y⁴ represent hydroxyl group, a |
| | | represents an integer from 58 to 63. The weight average |
| | | molecular weight is from about 8000 g/mol to about 8500 g/mol. |
| | A-2 | Structure represented by Formula (A-1), wherein Y¹, Y², and Y⁵ |
| | | represent hydrogen, Y³ and Y⁴ represent hydroxyl group, a |
| | | represents an integer from 14 to 23. The weight average |
| | | molecular weight is from about 2000 g/mol to about 3000 g/mol. |
| | A-3 | Structure represented by Formula (A-1), wherein Y¹, Y², and Y⁵ |
| | | represent hydrogen, Y³ and Y⁴ represent hydroxyl group, a |
| | | represents an integer from 51 to 56. The weight average |
| | | molecular weight is about 7000 g/mol to about 7500 g/mol. |
| | A-4 | Structure represented by Formula (A-1), wherein Y¹, Y², and Y⁵ |
| | | represent hydrogen, Y³ and Y⁴ represent hydroxyl group, a |
| | | represents an integer from 55 to 59. The weight average |
| | | molecular weight is about 7500 g/mol to about 8000 g/mol. |
| | A-5 | Structure represented by Formula (A-1), wherein Y¹, Y², and Y⁵ |
| | | represent hydrogen, Y³ and Y⁴ represent hydroxyl group, a |
| | | represents an integer from 62 to 67. The weight average |
| | | molecular weight is from about 8500 g/mol to about 9000 g/mol. |
| | A-6 | Structure represented by Formula (A-1), wherein Y¹, Y², and Y⁵ |
| | | represent hydrogen, Y³ and Y⁴ represent hydroxyl group, a |
| | | represents an integer from 66 to 74. The weight average |
| | | molecular weight is about 9000 g/mol to about 10000 g/mol. |
| | A-7 | Structure represented by the following Formula (A-3), where d represents an integer from 33 to 50. The weight average molecular weight is about 4000 g/mol to about 6000 g/mol. 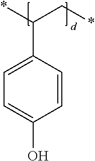 Formula (A-3) |
| Crosslinking | B-1 | Polymer composed of the first structural unit represented by |
| agent (B) | | Formula (B-1) and the second structural unit represented by |
| | | Formula (B-2), wherein in Formula (B-2), b represents 1; and the |
| | | molar ratio of the first structural unit to the second structural unit |
| | | is 80:20. |
| | | The weight average molecular weight is about 2000 g/mol to |
| | | about 10000 g/mol. |
| | B-2 | Polymer composed of the first structural unit represented by |
| | | Formula (B-1) and the second structural unit represented by |
| | | Formula (B-2), wherein in Formula (B-2), b represents 1; and the |
| | | molar ratio of the first structural unit to the second structural unit |
| | | is 50:50. |
| | | The weight average molecular weight is about 2000 g/mol to |
| | | about 10000 g/mol. |
| | B-3 | Polymer composed of the first structural unit represented by |
| | | Formula (B-1) and the second structural unit represented by |
| | | Formula (B-2), wherein in Formula (B-2), b represents 3; and the |
| | | molar ratio of the first structural unit to the second structural unit |
| | | is 80:20. |
| | | weight average molecular weight for about 2000 g/mol to about |
| | | 10000 g/mol. |
| | B-4 | Polymer composed of the first structural unit represented by |
| | | Formula (B-1) and the second structural unit represented by |
| | | Formula (B-2), wherein in Formula (B-2), b represents 5; and the |
| | | molar ratio of the first structural unit to the second structural unit |
| | | is 80:20. |
| | | weight average molecular weight for about 2000 g/mol to about |
| | | 10000 g/mol. |
| | B-5 | Polymer composed of the first structural units represented by |
| | | Formula (B-1). |
| | | The weight average molecular weight is about 1000 g/mol to |
| | | about 10000 g/mol. |
| | B-6 | Compound represented by the following Formula (B-3). 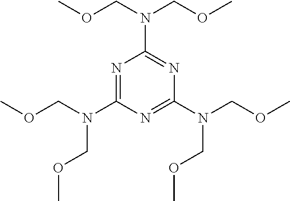 Formula (B-3) |
| | B-7 | Compound represented by the following Formula (B-4). 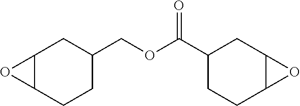 [SMILES: O=C(OCC1CCC2OC2C1)C1CCC2OC2C1] Formula (B-4) |
| | B-8 | Compound represented by the following Formula (B-5), wherein e represents an integer of 7 to 8. 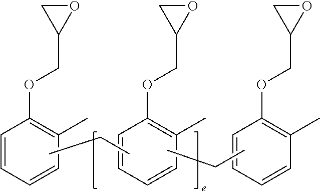 Formula (B-5) |
| | B-9 | Compound represented by the following Formula (B-6). 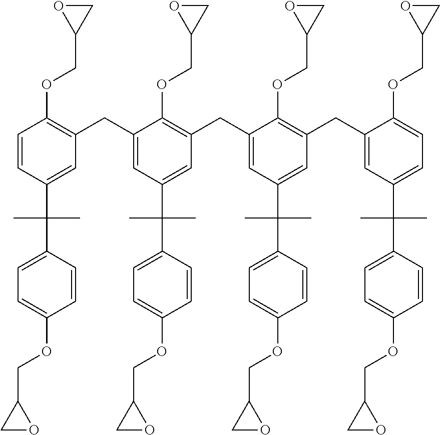 [SMILES: CC(C)(c1ccc(OCC2CO2)cc1)c1ccc(OCC2CO2)c(Cc2cc(C(C)(C)c3ccc(OCC4CO4)cc3)cc(Cc3cc(C(C)(C)c4ccc(OCC5CO5)cc4)cc(Cc4cc(C(C)(C)c5ccc(OCC6CO6)cc5)ccc4OCC4CO4)c3OCC3CO3)c2OCC2CO2)c1] Formula (B-6) |
| | B-10 | 1,4-Butanediol dimethacrylate (BDDMA) |
| | B-11 | Neopentyl glycol dimethacrylate (NPGDMA) |
| | B-12 | Compound represented by the following Formula (B-7), wherein f is 10. 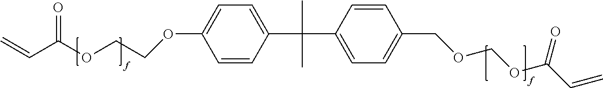 Formula (B-7) |
| | B-13 | Compound represented by the following Formula (B-8), wherein g and h each represent an integer, and a sum thereof is 10. 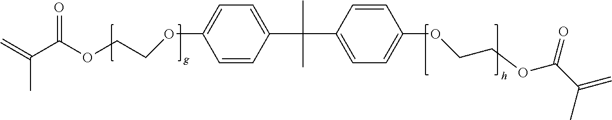 Formula (B-8) |
| | B-14 | Compound represented by the following Formula (B-9), wherein j and k each represent an integer, and a sum thereof is 20. 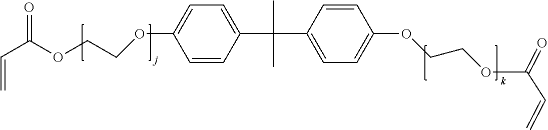 Formula (B-9) |
| | B-15 | Triethylene glycol diacrylate (TEGDA) |
| | B-16 | Compound represented by the following Formula (B-10). 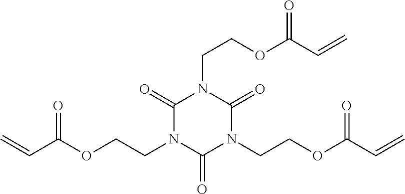 [SMILES: C=CC(=O)OCCn1c(=O)n(CCOC(=O)C=C)c(=O)n(CCOC(=O)C=C)c1=O] Formula (B-10) |
| | B-17 | Cyclic trimethylolpropane formal acrylate (CTFA) |
| | B-18 | Propoxylated tetrahydrofurfuryl acrylate (THF(PO)3A) |
| solvent (C) | C-1 | Propylene glycol monomethyl ether acetate (PGMEA) |
| additive (D) | D-1 | Compound represented by the following Formula (D-1), wherein m and n each represent an integer, and a sum thereof is 6; q is 20. 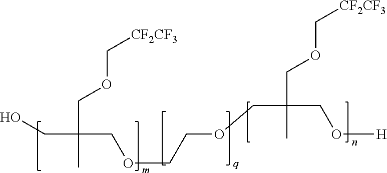 Formula (D-1) |

TABLE 2

| Component | | Example | | | | | | |
|---|---|---|---|---|---|---|---|---|
| <Unit: parts by weight> | | 1 | 2 | 3 | 4 | 5 | 6 | 7 |
| Resin (A) | A-1 | 100 | 100 | — | — | — | — | — |
| | A-2 | — | — | 100 | — | — | — | — |
| | A-3 | — | — | — | 100 | — | — | — |
| | A-4 | — | — | — | — | 100 | — | — |
| | A-5 | — | — | — | — | — | 100 | — |
| | A-6 | — | — | — | — | — | — | 100 |
| | A-7 | — | — | — | — | — | — | — |
| Crosslinking | B-1 | 66.67 | 66.67 | 66.67 | 66.67 | 66.67 | 66.67 | 66.67 |
| agent (B) | B-2 | — | — | — | — | — | — | — |
| | B-3 | — | — | — | — | — | — | — |
| | B-4 | — | — | — | — | — | — | — |
| | B-5 | — | — | — | — | — | — | — |
| | B-6 | — | — | — | — | — | — | — |
| | B-7 | — | — | — | — | — | — | — |
| | B-8 | — | — | — | — | — | — | — |
| | B-9 | — | — | — | — | — | — | — |
| | B-10 | — | — | — | — | — | — | — |
| | B-11 | — | — | — | — | — | — | — |
| | B-12 | — | — | — | — | — | — | — |
| | B-13 | — | — | — | — | — | — | — |
| | B-14 | — | — | — | — | — | — | — |
| | B-15 | — | — | — | — | — | — | — |
| | B-16 | — | — | — | — | — | — | — |
| | B-17 | — | — | — | — | — | — | — |
| | B-18 | — | — | — | — | — | — | — |
| Solvent (C) | C-1 | 40482 | 40484 | 40482 | 40482 | 40482 | 40482 | 40482 |
| Additive (D) | D-1 | 2.033 | — | 2.033 | 2.033 | 2.033 | 2.033 | 2.033 |
| Evaluation | Refractive index | 1.49 | 1.50 | 1.48 | 1.49 | 1.48 | 1.48 | 1.49 |
| Result | Absorption rate | 0.48 | 0.47 | 0.46 | 0.50 | 0.52 | 0.52 | 0.51 |
| | Flatness (Å) | 0.83 | 1.82 | 0.24 | 0.91 | 0.71 | 0.8 | 0.95 |
| | Chemical | 0.06 | 0.54 | 0.49 | 0.23 | 0.02 | 0.44 | 0.03 |
| | resistance (%) | | | | | | | |
| | Etchability | 0.74 | 0.40 | 1.14 | 1.29 | 0.91 | 0.39 | 0.30 |
| | resistance (%) | | | | | | | |

| Component | | Example | | | | | |
|---|---|---|---|---|---|---|---|
| <Unit: parts by weight> | | 8 | 9 | 10 | 11 | 12 | 13 |
| Resin (A) | A-1 | 100 | 100 | 100 | 100 | 100 | 100 |
| | A-2 | — | — | — | — | — | — |
| | A-3 | — | — | — | — | — | — |
| | A-4 | — | — | — | — | — | — |
| | A-5 | — | — | — | — | — | — |
| | A-6 | — | — | — | — | — | — |
| | A-7 | — | — | — | — | — | — |
| Crosslinking | B-1 | — | — | — | — | — | — |
| agent (B) | B-2 | 66.67 | 100.00 | — | — | — | — |
| | B-3 | — | — | 66.67 | 100.00 | — | — |
| | B-4 | — | — | — | — | 66.67 | 100.00 |
| | B-5 | — | — | — | — | — | — |
| | B-6 | — | 50.00 | — | 50.00 | — | 50.00 |
| | B-7 | — | — | — | — | — | — |
| | B-8 | — | — | — | — | — | — |
| | B-9 | — | — | — | — | — | — |
| | B-10 | — | — | — | — | — | — |
| | B-11 | — | — | — | — | — | — |
| | B-12 | — | — | — | — | — | — |
| | B-13 | — | — | — | — | — | — |
| | B-14 | — | — | — | — | — | — |
| | B-15 | — | — | — | — | — | — |
| | B-16 | — | — | — | — | — | — |
| | B-17 | — | — | — | — | — | — |
| | B-18 | — | — | — | — | — | — |
| Solvent (C) | C-1 | 40482 | 60723 | 40482 | 60723 | 40482 | 60723 |
| Additive (D) | D-1 | 2.033 | 3.049 | 2.033 | 3.049 | 2.033 | 3.049 |
| Evaluation | Refractive index | 1.45 | 1.49 | 1.43 | 1.50 | 1.43 | 1.51 |
| Result | Absorption rate | 0.56 | 0.35 | 0.56 | 0.33 | 0.55 | 0.32 |
| | Flatness (Å) | 0.48 | 0.55 | 0.66 | 0.63 | 0.48 | 0.42 |
| | Chemical | 0.72 | 0.56 | 0.39 | 0.56 | 0.12 | 0.14 |
| | resistance (%) | | | | | | |
| | Etchability | 1.52 | 1.92 | 1.22 | 1.94 | 1.00 | 1.67 |
| | resistance (%) | | | | | | |

| Component | | Comparative Example | | | | | | |
|---|---|---|---|---|---|---|---|---|
| <Unit: parts by weight> | | 1 | 2 | 3 | 4 | 5 | 6 | 7 |
| Resin (A) | A-1 | — | 100 | 100 | 100 | 100 | 100 | 100 |
| | A-2 | — | — | — | — | — | — | — |
| | A-3 | — | — | — | — | — | — | — |
| | A-4 | — | — | — | — | — | — | — |
| | A-5 | — | — | — | — | — | — | — |
| | A-6 | — | — | — | — | — | — | — |
| | A-7 | 100 | — | — | — | — | — | — |
| Crosslinking | B-1 | 100.00 | 200.00 | — | — | — | — | — |
| agent (B) | B-2 | — | — | — | — | — | — | — |
| | B-3 | — | — | — | — | — | — | — |
| | B-4 | — | — | — | — | — | — | — |
| | B-5 | — | — | — | — | — | — | 50.00 |
| | B-6 | 50.00 | 200.00 | 25.00 | — | — | — | — |
| | B-7 | — | — | — | 66.67 | — | — | — |
| | B-8 | — | — | — | — | 66.67 | — | — |
| | B-9 | — | — | — | — | — | 66.67 | — |
| | B-10 | — | — | — | — | — | — | 16.67 |
| | B-11 | — | — | — | — | — | — | — |
| | B-12 | — | — | — | — | — | — | — |
| | B-13 | — | — | — | — | — | — | — |
| | B-14 | — | — | — | — | — | — | — |
| | B-15 | — | — | — | — | — | — | — |
| | B-16 | — | — | — | — | — | — | — |
| | B-17 | — | — | — | — | — | — | — |
| | B-18 | — | — | — | — | — | — | — |
| Solvent (C) | C-1 | 60723 | 121445 | 30361 | 40482 | 40482 | 40482 | 40482 |
| Additive (D) | D-1 | 3.049 | 6.098 | 1.524 | 2.033 | 2.033 | 2.033 | 2.033 |
| Evaluation | Refractive | 1.56 | 1.51 | 1.38 | 1.42 | 1.34 | 1.42 | 1.44 |
| Result | index | | | | | | | |
| | Absorption | 0.53 | 0.26 | 0.65 | 0.58 | 0.63 | 0.66 | 0.55 |
| | rate | | | | | | | |
| | Flatness (Å) | 0.89 | 0.53 | 1.04 | 0.91 | 0.6 | 0.75 | 0.61 |
| | Chemical | 1.42 | 0.20 | 3.48 | 40.83 | 10.40 | 2.38 | 7.77 |
| | resistance (%) | | | | | | | |
| | Etchability | 4.40 | 6.15 | 4.29 | — | — | — | — |
| | resistance (%) | | | | | | | |

| Component | | Comparative Example | | | | | | | |
|---|---|---|---|---|---|---|---|---|---|
| <Unit: parts by weight> | | 8 | 9 | 10 | 11 | 12 | 13 | 14 | 15 |
| Resin (A) | A-1 | 100 | 100 | 100 | 100 | 100 | 100 | 100 | 100 |
| | A-2 | — | — | — | — | — | — | — | — |
| | A-3 | — | — | — | — | — | — | — | — |
| | A-4 | — | — | — | — | — | — | — | — |
| | A-5 | — | — | — | — | — | — | — | — |
| | A-6 | — | — | — | — | — | — | — | — |
| | A-7 | — | — | — | — | — | — | — | — |
| Crosslinking | B-1 | — | — | — | — | — | — | — | — |
| agent (B) | B-2 | — | — | — | — | — | — | — | — |
| | B-3 | — | — | — | — | — | — | — | — |
| | B-4 | — | — | — | — | — | — | — | — |
| | B-5 | 50.00 | 50.00 | 50.00 | 50.00 | 50.00 | 50.00 | 50.00 | 50.00 |
| | B-6 | — | — | — | — | — | — | — | — |
| | B-7 | — | — | — | — | — | — | — | — |
| | B-8 | — | — | — | — | — | — | — | — |
| | B-9 | — | — | — | — | — | — | — | — |
| | B-10 | — | — | — | — | — | — | — | — |
| | B-11 | 16.67 | — | — | — | — | — | — | — |
| | B-12 | — | 16.67 | — | — | — | — | — | — |
| | B-13 | — | — | 16.67 | — | — | — | — | — |
| | B-14 | — | — | — | 16.67 | — | — | — | — |
| | B-15 | — | — | — | — | 16.67 | — | — | — |
| | B-16 | — | — | — | — | — | 16.67 | — | — |
| | B-17 | — | — | — | — | — | — | 16.67 | — |
| | B-18 | — | — | — | — | — | — | — | 16.67 |
| Solvent (C) | C-1 | 40482 | 40482 | 40482 | 40482 | 40482 | 40482 | 40482 | 40482 |
| Additive (D) | D-1 | 2.033 | 2.033 | 2.033 | 2.033 | 2.033 | 2.033 | 2.033 | 2.033 |
| Evaluation | Refractive | 1.42 | 1.44 | 1.43 | 1.41 | 1.44 | 1.42 | 1.42 | 1.42 |
| Result | index | | | | | | | | |
| | Absorption | 0.55 | 0.55 | 0.55 | 0.54 | 0.55 | 0.55 | 0.55 | 0.55 |
| | rate | | | | | | | | |
| | Flatness (Å) | 0.76 | 0.44 | 1.04 | 0.92 | 0.37 | 0.4 | 0.38 | 0.48 |
| | Chemical | 6.36 | 2.41 | 6.33 | 2.61 | 2.68 | 2.49 | 2.67 | 3.03 |
| | resistance (%) | | | | | | | | |
| | Etchability | — | — | — | — | — | — | — | — |
| | resistance (%) | | | | | | | | |

*When the resin composition did not pass the chemical resistance test (for example, when the film thickness change rate was much greater than 1.2%), the etchability resistance test was not performed.

### Evaluation Method

a. Refractive Index

Each of the prepared resin compositions was coated on a silicon substrate. After baking, the resin composition was cured to form a cured layer with a thickness of 100±50 Å. The refractive index (n) at a wavelength of 193 nm was then measured by an ellipsometer (model: M-2000VI, manufactured by Titan Electro-Optics Co., Ltd.). When the refractive index is higher (for example, greater than 1.4), the cured layer has good effect of reducing light reflection.

### B. Absorption Rate

Each of the prepared resin compositions was coated on a silicon substrate. After baking, the resin composition was cured to form a cured layer with a thickness of 100±50 Å. The absorption rate (k) at a wavelength of 193 nm was then measured by an ellipsometer (model: M-2000VI, manufactured by Titan Electro-Optics Co., Ltd.). When the absorption rate is smaller (for example, less than 0.6), the cured layer has a good effect of reducing light reflection.

c. Flatness

Each of the prepared resin compositions was coated on a silicon substrate. After baking, the resin composition was cured to form a cured layer with a thickness of 100±50 Å. Then, an ellipsometer was used to measure the film thickness at 5 different points on each substrate having the cured layer formed thereon. The minimum value of the film thickness was subtracted from the maximum value to obtain a film thickness difference. When the film thickness difference is smaller (for example, less than 5 Å), the cured layer has good flatness, i.e., good uniformity.

d. Chemical Resistance

The substrate that completed the flatness test was soaked in an etching solution (PGMEA:PGME=3:7 (weight ratio)) in an environment of 25±5° C. After soaking for 2 minutes, it was rinsed with ultrapure water to remove excess solvent. Then, the film thickness after soaking was measured at the same position of 5 points as before soaking. The film thickness change rate may be calculated from the film thickness values before and after soaking. When the film thickness change rate is smaller (for example, less than 1.2%), the cured layer has good chemical resistance.

$$\text{film thickness change rate} = \frac{\vert {\text{film thickness}}_{\text{before soaking}} - {\text{film thickness}}_{\text{after soaking}} \vert}{{\text{film thickness}}_{\text{before soaking}}} \times 100 \%$$

e. Etchability Resistance

The substrate that completed the flatness test was soaked in an alkaline etching solution (ammonia water:hydrogen peroxide:water=1:1:5 (weight ratio)) in an environment of 25±5° C. After soaking for 10 minutes, it was rinsed with ultrapure water to remove excess solvent. Then, the film thickness after soaking was measured at the same position of 5 points as before soaking. The film thickness change rate may be calculated from the film thickness values before and after soaking. When the film thickness change rate is smaller (for example, less than 2.5%), the cured layer has good etchability resistance (for example, alkali resistance property).

$$\text{film thickness change rate} = \frac{\vert {\text{film thickness}}_{\text{before soaking}} - {\text{film thickness}}_{\text{after soaking}} \vert}{{\text{film thickness}}_{\text{before soaking}}} \times 100 \%$$

### Evaluation Results

As may be seen from Table 2, the cured layer formed by the Examples where the resin composition includes the resin (A) having a specific structure and the crosslinking agent (B) including a polymer having a specific structure and the usage amount thereof has good refractive index, absorption rate, flatness, and film thickness change rate, i.e., has good refractive index, absorption rate, flatness, chemical resistance, and etchability resistance, and may be applicable to semiconductor process. On the other hand, the cured layer formed by the Comparative Examples where the resin composition does not include the resin (A) having a specific structure, the crosslinking agent (B) including a polymer having a specific structure, and/or the usage amount range of the specific crosslinking agent (B) has poor refractive index, absorption rate, flatness, chemical resistance, and/or etchability resistance.

In addition, as may be seen from Table 2, compared to the cured layer prepared from the resin composition that does not include the resin (A) having a specific structure (Comparative Example 1), the cured layer prepared from the resin composition including the resin (A) having a specific structure (Examples 1 to 13) have smaller film thickness change rate after soaking in the etching solution, i.e., have better chemical resistance and etchability resistance. Therefore, when the resin (A) includes the specific structure represented by Formula (A-1), the cured layer formed by the resin composition including the same may have better chemical resistance and etchability resistance, and simultaneously have good refractive index, absorption rate, and flatness.

In addition, as may be seen from Table 2, in the case where the difference in components composing the resin composition is only the usage amount, compared to the cured layer prepared when the usage amount of the crosslinking agent (B) in the resin composition is not within the range of 60 parts by weight to 150 parts by weight based on 100 parts by weight of the resin (A) (Comparative Example 2), the cured layers prepared when the usage amount of the crosslinking agent (B) in the resin composition is within the range of 60 parts by weight to 150 parts by weight (Examples 1 to 13) have smaller film thickness change rate after soaking in the alkaline etching solution, i.e., have better etchability resistance (for example, alkali resistance property). Therefore, when the usage amount of the crosslinking agent (B) is within the range of 60 parts by weight to 150 parts by weight, the cured layer formed by the resin composition including the same may have better etchability resistance (for example, alkali resistance property), and simultaneously have good refractive index, absorption rate, flatness, and chemical resistance.

In addition, as may be seen from Table 2, compared to the cured layer prepared from the resin composition that does not include the crosslinking agent (B) having a specific structure, and the usage amount of the crosslinking agent (B) in the resin composition is not within the range of 60 parts by weight to 150 parts by weight based on 100 parts by weight of the resin (A) (Comparative Example 3), the cured layers prepared from the resin composition including the crosslinking agent (B) having a specific structure, and the usage amount of the crosslinking agent (B) is within the range of 60 parts by weight to 150 parts by weight (Examples 1 to 13) have larger refractive index, smaller absorption rate, and smaller film thickness change rate, i.e., have better refractive index, absorption rate, chemical resistance, and etchability resistance, and simultaneously have good flatness.

In addition, as may be seen from Table 2, compared to the cured layers prepared from the resin composition that does not include the crosslinking agent (B) having a specific structure (Comparative Examples 3 to 15), the cured layers prepared from the resin composition including the crosslinking agent (B) having a specific structure (Examples 1 to 13) have smaller film thickness change rates after soaking in the etching solution, i.e., have better chemical resistance and etchability resistance. Therefore, when the crosslinking agent (B) includes a polymer including the first structural unit represented by Formula (B-1) and the second structural unit represented by Formula (B-2), the cured layer formed by the resin composition including the same may have better chemical resistance and etchability resistance, and simultaneously have good refractive index, absorption rate, and flatness.

In addition, as may be seen from Table 2, when the weight average molecular weight of the resin (A) is about 2000 g/mol to about 10000 g/mol, the cured layer formed by the resin composition including the same may have a refractive index greater than 1.4, an absorption rate less than 0.6, a film thickness difference less than 5 Å, a film thickness change rate less than 1.2% after soaking in etching solution (PGMEA:PGME=3:7), and a film thickness change rate less than 2.5% after soaking in alkaline etching solution, i.e., have good refractive index, absorption rate, flatness, chemical resistance, and etchability resistance.

In summary, the resin composition of the invention includes the resin (A) having a specific structure and the crosslinking agent (B) including a polymer having a specific structure, and when the usage amount of the crosslinking agent (B) is within the range of 60 parts by weight to 150 parts by weight based on 100 parts by weight of the resin (A), the cured layer formed by the resin composition has high refractive index, low absorption rate, good flatness, chemical resistance, and etchability resistance, and may be applicable to etching method and semiconductor process, thereby improving the performance of semiconductor devices manufactured using it. In addition, the cured layer formed by the resin composition of the invention may enable a pattern subsequently formed on the cured layer to have good lithographic pattern clarity and accuracy.

Although the invention has been disclosed above with examples, they are not used to limit the invention. Any person having ordinary knowledge in the technical field may make slight modifications and refinements without departing from the spirit and scope of the invention. Therefore, the protection scope of the invention shall be determined by the appended claims.

What is claimed is:

1. A resin composition, comprising:
a resin (A), comprising a structure represented by the following Formula (A-1);
a crosslinking agent (B), comprising a polymer, the polymer comprising a first structural unit represented by the following Formula (B-1) and a second structural unit represented by the following Formula (B-2); and
a solvent (C),
wherein based on a usage amount of the resin (A) being 100 parts by weight, a usage amount of the crosslinking agent (B) is 60 parts by weight to 150 parts by weight, and a usage amount of the solvent (C) is 2400 parts by weight to 99900 parts by weight: 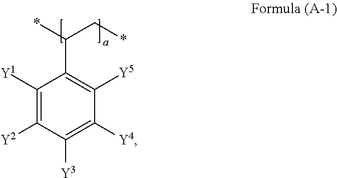
in Formula (A-1), Y¹ to Y⁵ each represent hydrogen or hydroxyl group, and at least two of Y¹ to Y⁵ represent hydroxyl group,
a represents an integer of 5 to 220; and
* represents a bonding position; 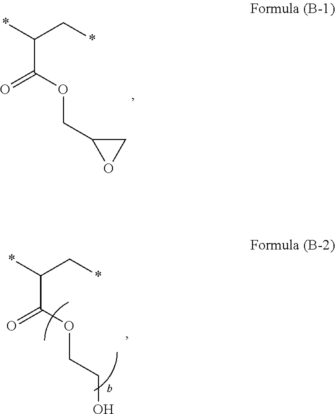
in Formula (B-1) and Formula (B-2), b represents an integer of 1 to 6; and
* represents a bonding position.

2. The resin composition according to claim 1, wherein a molar ratio of the first structural unit to the second structural unit is 50:50 to 95:5.

3. The resin composition according to claim 1, wherein a weight average molecular weight of the polymer comprised in the crosslinking agent (B) is 2000 g/mol to 20000 g/mol.

4. The resin composition according to claim 1, wherein in Formula (A-1), two of Y¹ to Y⁵ are hydroxyl groups.

5. The resin composition according to claim 1, wherein the resin (A) comprises a structural unit represented by the following Formula (A-2): 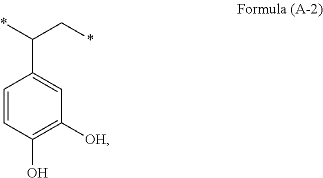
in Formula (A-2), * represents a bonding position;
a weight average molecular weight of the resin (A) is 2000 g/mol to 20000 g/mol.

6. The resin composition according to claim 1, wherein the crosslinking agent (B) further comprises a triazine-based compound, a compound having a monomethacrylate functional group, a compound having a dimethacrylate functional group, or a combination thereof.

7. The resin composition according to claim 1, wherein the solvent (C) comprises propylene glycol methyl ether, propylene glycol monomethyl ether acetate, or a combination thereof.

8. The resin composition according to claim 1, further comprising an additive (D), wherein the additive (D) comprises a dispersant, a defoaming agent, a wetting agent, an emulsifier, a leveling agent, an antioxidant, a thermal acid generator, or a combination thereof.

9. The resin composition according to claim 1, further comprising an additive (D), wherein based on a usage amount of the resin (A) being 100 parts by weight, a usage amount of the additive (D) is greater than 0 part by weight and less than or equal to 25 parts by weight.

10. A cured layer, formed by curing the resin composition according to claim 1.

11. A manufacturing method of a cured layer, comprising:
coating the resin composition according to claim 1 on a substrate to form a coating film; and
baking the coating film to form a cured layer.

12. The manufacturing method of a cured layer according to claim 11, wherein the baking is performed at a temperature of 150° C. to 250° C.

13. An etching method, comprising: soaking the cured layer according to claim 10 in an etching solution to perform an etching process.

14. The etching method according to claim 13, wherein the etching solution comprises propylene glycol monomethyl ether acetate, propylene glycol methyl ether, ammonium hydroxide, hydrogen peroxide, water, tetramethylammonium hydroxide, or a combination thereof.

15. An etching method, comprising: soaking the cured layer formed by the manufacturing method of a cured layer according to claim 11 in an etching solution to perform an etching process.

16. The etching method according to claim 15, wherein the etching solution comprises propylene glycol monomethyl ether acetate, propylene glycol methyl ether, ammonium hydroxide, hydrogen peroxide, water, tetramethylammonium hydroxide, or a combination thereof.
